(19) United States
(12) Patent Application Publication
(10) Pub. No.: US 2005/0111196 A1
(43) Pub. Date: May 26, 2005

(54) Fastening structure of heat sink

(76) Inventors: Jack Wang, Taoyuan City (TW); Cheng-Hua Cheng, Taoyuan City (TW); Michael Lin, Taoyuan City (TW); Charles Ma, Taoyuan City (TW)

Correspondence Address: HDSL, 4331 STEVENS BATTLE LANE, FAIRFAX, VA, 22033, US

(21) Appl. No.: 10/717,449

(22) Filed: Nov. 21, 2003

(51) Int. Cl. H05K 7/20

(52) U.S. Cl. 361/719; 361/704; 361/709; 248/507; 248/510; 257/718

(57) ABSTRACT

A fastening structure used for fastening a heat sink to a heat generating device formed on a board is disclosed. The heat sink has a plurality of vertically extending fins spaced by each other by a first gap, and the fastening structure has a pair of blocking members applied to two outermost fins of the heat sink. Each of the blocking members has a horizontal plate, a pair of arms extending from two opposing sides of the horizontal plate, a vertical plate extending perpendicularly from one end of the horizontal plate, a pair of wings extending from two opposing sides of the vertical plates, and a pair of resilient flaps extending from top edges of the wings. Each of the arms is terminated with a hook, and each of the block members further has a pair of loops formed on the board, such that by engaging the hooks with the loops, the fastening structure secures the heat sink to the heat generating device on the board.

### BACKGROUND OF THE INVENTION

The present invention relates to a fastening structure of a heat sink, and more particular, to a structure to prevent loose or displacement of a heat sink.

As the operation speed of the electronic devices such as computer, personal data assistance becomes faster and faster, the internal temperature of the electronic devices increases higher and higher. To effectively dissipate heat generated in the electronic devices and maintain various components of the electronic devices operating under tolerable temperatures, heat sinks or heat dissipating devices have become necessary devices for current electronic devices. Normally, heat sinks are mounted to the heat generating devices such as chip or central processing unit on a motherboard of the electronic devices by fastening structures. By stably mounting the heat sinks, heat generated by the electronic devices can be efficiently dissipated, and the electronic devices can operate normally.

However, when the electronic devices loosen or displace from the desired position, the assembly of the electronic devices becomes difficult, and the heat dissipation of the electronic devices is problematic. Further, for different types of heat sinks, a great variety of fastening structures and methods have been used. Currently, no standard designs of fastening structures have been developed. The application flexibility is thus very limited.

### BRIEF SUMMARY OF THE INVENTION

The present invention provides a fastening structure for securing a heat sink to a heat generating device formed on a board, such that the heat sink is prevented from loosening or displacing away from the heat generating device.

The heat sink includes a plurality of vertically extending fins spaced by each other by a first gap, and the fastening structure comprises a pair of blocking members. Each of the blocking members comprises a horizontal plate, a pair of arms extending from two opposing sides of the horizontal plate, a vertical plate extending perpendicularly from one end of the horizontal plate, a pair of wings extending from two opposing sides of the vertical plates, and a pair of resilient flaps extending from top edges of the wings. Each of the arms is terminated with a hook, and each of the block members further comprises a pair of loops formed on the board, such that by engaging the hooks with the loops, the fastening structure secures the heat sink to the heat generating device on the board.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These, as well as other features of the present invention, will become apparent upon reference to the drawings wherein:

FIG. 1 shows an exploded view of a fastening structure of a heat sink provided by the present invention;

FIG. 2 shows a perspective view of the assembly of the fastening structure as shown in FIG. 1;

FIG. 3 shows a side view of the fastening structure as shown in FIG. 2;

FIG. 4 shows a cross sectional view of the fastening structure as shown in FIG. 2;

FIG. 5 shows an application of the fastening structure as shown in FIG. 2;

FIG. 6 shows another application of the fastening structure as shown in FIG. 2; and

FIG. 7 shows yet another application of the fastening structure as shown in FIG. 2.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

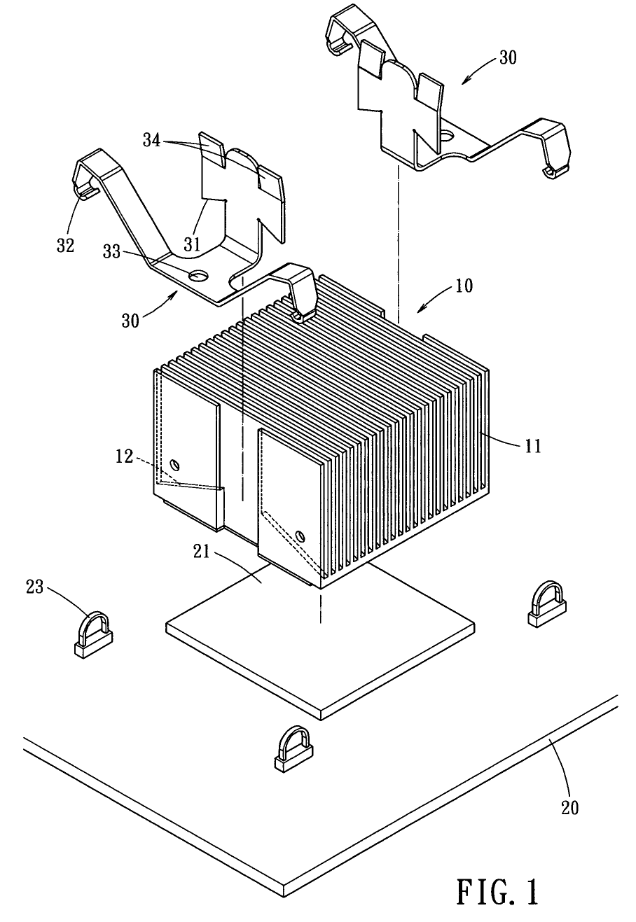

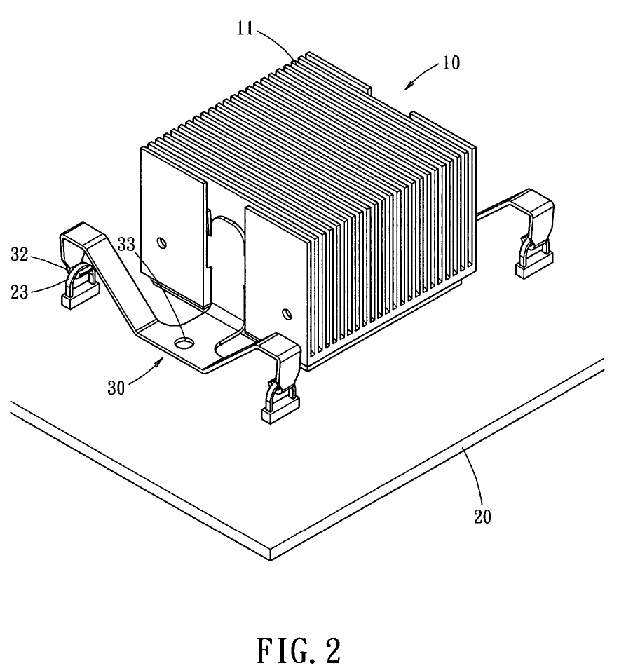

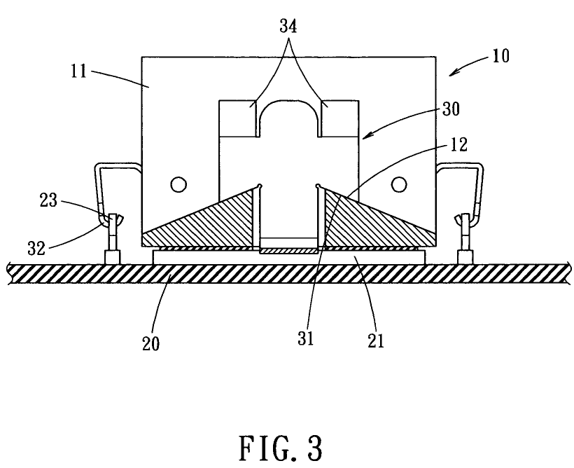

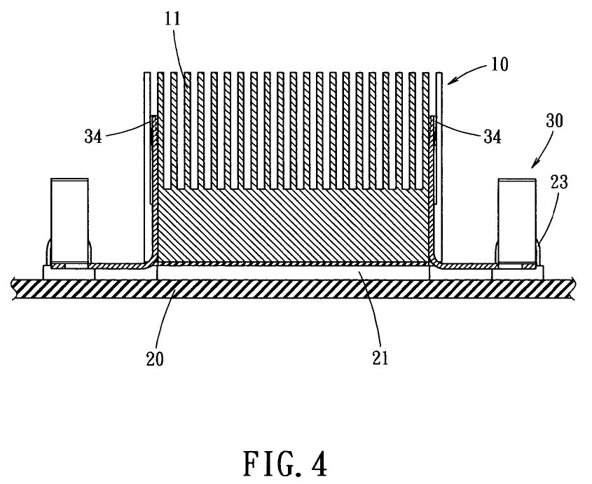

As shown in FIGS. 1 to 4, the present invention provides a fastening structure to avoid loosening or displacement of a heat sink. The heat sink 10 is fabricated from material with good thermal conductivity such as aluminum or copper. Thermal conductive paste or adhesive is often applied to a bottom surface of the heat sink 10, such that the heat sink 10 can be attached on a heat generating device 21 (such as chip or central processing unit) on a motherboard 20 (as shown in FIG. 2) of an electronic product.

The heat sink 10 includes a plurality of fins 11 spaced with each other by a gap. As shown, each of the fins 11 includes a rectangular shape extending vertically. In this embodiment, each of the outermost fins 11 is cut into two rectangular members spaced with each other by a gap, and the inner surface of each rectangular member is further processed to form an upper inner surface and a lower inner surface protruding from the upper inner surface. The lower inner surface has a top edge 12 gradually descending from the gap between the rectangular members.

The fastening structure 30 includes a pair of locking members to hold or secure the heat sink at two outermost fins 11. As shown in FIG. 1, each locking member comprises a horizontal plate, a vertical plate extending perpendicularly from one end of the horizontal plate. Extending from two sides of the horizontal plate include a pair of arms each terminating with a hook 32. To secure the locking member to a motherboard 20 on which a heat generating device 21 is formed, a pair of loops 23 eagageable with the hooks 32 is mounted on the motherboard 20.

The vertical plate of each locking member includes a substantially rectangular central portion and a pair of wings 31 extending from two lateral opposing sides of the rectangular central portion, and a pair of resilient flaps 34 extending from top edge of the wings 31. As shown, the rectangular central portion and the wings 31 are substantially planar, while the resilient flaps 34 are slightly inclined towards horizontal plate. The lower edges of the wings 31 gradually descend from the central portion.

To hold the heat sink 10, the horizontal plates of the locking members are inserted into the space between the outermost fins 11 and the fin 11 next to the outermost fins 11. When the lower edges 31 of the locking members are inserted above the protruding edges 12, the slightly bending resilient flaps 34 exerts a force against the upper inner surfaces of the outermost fins 11, while the protruding edges 12 block the wings 31 to slide or move downwardly. Thereby, the locking members of the fastening structure 30 are engaged with the heat sink 10. By engaging the hooks 32 with the loops 23, the heat sink 10 engaged with the fastening structure 30 is then secured to the motherboard 20 on the heat generating device 21.

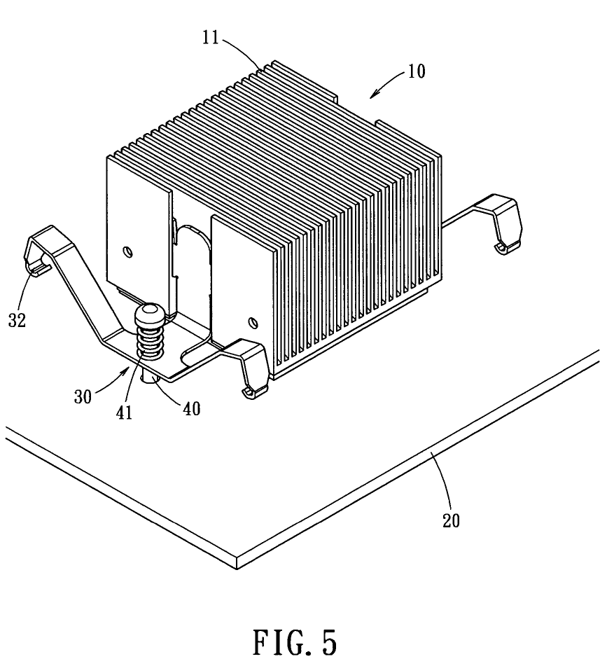

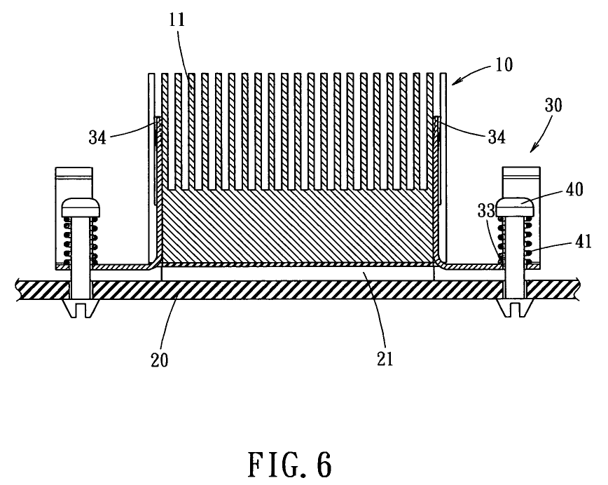

The horizontal plate of each block member may further comprises a through hole 33. Therefore, the locking members can be further secured to the motherboard 20 by fasteners 40 and 41 as shown in FIGS. 5 and 6.

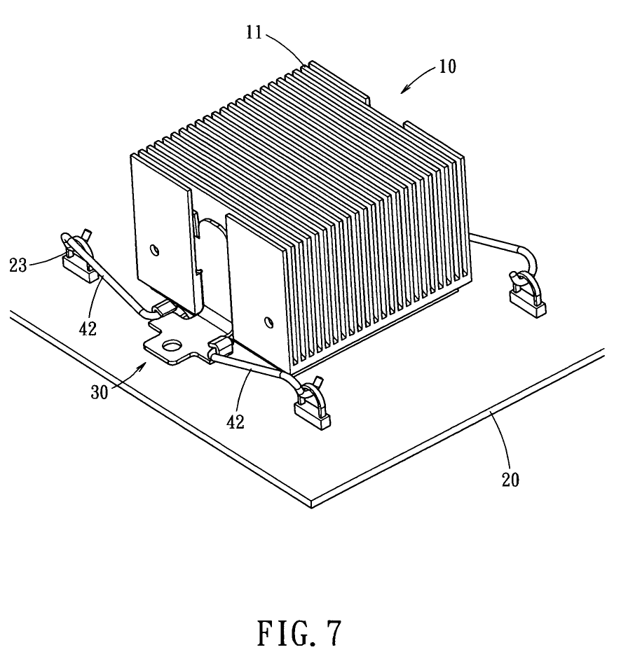

FIG. 7 shows another embodiment of the arms extending from two sides of the horizontal plates of the locking members. As shown, the sides of each horizontal plate are terminated with a hinge, and the proximal ends of the arms 42 are engaged with the hinges such that the arms 42 can be turned about the hinges. Similarly to the above embodiment, the distal ends of the arms 42 are terminated with the hooks engageable with the loops 23 mounted to the motherboard 20.

The fastening structure provided by the present invention has at least the following advantages.

1. The heat sink is prevented from loosening or displacing away from the heat generating device.

2. The fastening structure can be easily attached to and detached from the heat sink.

3. The fastening structure can be applied to heat sinks with various configuration.

This disclosure provides exemplary embodiments of the present invention. The scope of this disclosure is not limited by these exemplary embodiments. Numerous variations, whether explicitly provided for by the specification or implied by the specification, such as variations in shape, structure, dimension, type of material or manufacturing process may be implemented by one of skill in the art in view of this disclosure.

1. A fastening structure of a heat sink having a plurality of fins spaced from each other by a first gap, the fastening structure comprising a pair of locking members, and each of the locking members including at least one resilient flap to be inserted into one of the first gaps.

2. The fastening structure of claim 1, wherein each of the locking members further includes a vertical plate, the vertical plate includes the flap extending from a top edge thereof and a pair of wings extending from two opposing side edges thereof.

3. The fastening structure of claim 2, wherein the outermost fins of the heat sink is partitioned into two rectangular members separated to each other by a second gap, each including an upper inner surface and a lower inner surface protruding from the inner surface, and each of the lower inner surfaces has a top edge descending gradually from the second gap.

4. The fastening structure of claim 1, wherein each locking member further comprising a pair of hooks and a pair of loops engageable with the hooks.

5. A fastening structure to secure a heat sink to a heat generating device on a board, the heat sink includes a plurality of vertically extending fins spaced by each other by a first gap, the fastening structure comprising:
a pair of blocking members, each comprising:
a horizontal plate;
a pair of arms extending from two opposing sides of the horizontal plate, each of the arms terminated with a hook;
a pair of loops formed on the board, the loops being positioned and configured to be engageable with the hooks;
a vertical plate extending perpendicularly from one end of the horizontal plate;
a pair of wings extending from two opposing sides of the vertical plates; and
a pair of resilient flaps extending from top edges of the wings.

6. The fastening structure of claim 5, wherein each of the two outermost fins of the heat sink is partitioned into two rectangular members spaced with each other by a second gap.

7. The fastening structure of claim 6, wherein each rectangular member has an inner surface, and the inner surface includes an upper portion and a lower portion protruding from the upper portion.

8. The fastening structure of claim 7, wherein the lower portion has a top edge gradually descending from the second gap.

9. The fastening structure of claim 8, wherein each of the wings has a lower edge gradually descending from two sides of the vertical plate.

10. The fastening structure of claim 5, wherein the resilient flaps are operative to exert a force against the outermost fins when the vertical plates are inserted between the outermost fins and the fins next thereto.

11. The fastening structure of claim 5, wherein the horizontal plate further comprises a through hole and a fastener to fasten the horizontal plate with the board.
